(19) United States
(12) Patent Application Publication
(10) Pub. No.: US 2013/0049106 A1
(43) Pub. Date: Feb. 28, 2013

(54) BIDIRECTIONAL SEMICONDUCTOR DEVICE AND METHOD OF FABRICATING THE SAME

(71) Applicant: Wei-Chieh Lin, Hsinchu City (TW)

(72) Inventor: Wei-Chieh Lin, Hsinchu City (TW)

(21) Appl. No.: 13/523,841

(22) Filed: Jun. 14, 2012

(30) Foreign Application Priority Data
Aug. 22, 2011 (CN) 201110243112.6

(51) Int. Cl. H01L 27/092; H01L 21/8238

(52) U.S. Cl. 257/331; 438/212; 257/E27.062; 257/E21.632

(57) ABSTRACT

The present invention provides a bidirectional semiconductor device including a semiconductor substrate having a first conductive type, a first doped base region and a second doped base region having a second conductive type, and a gate insulating layer. The semiconductor substrate has a first trench, and the first doped base region and the second doped base region are respectively disposed in the semiconductor substrate at two sides of the first trench. The gate insulating layer covers a surface of the first trench, and the gate insulating layer has a first part adjacent to the first doped base region, a second part adjacent to the second doped base region, and a third part disposed at a corner between a bottom and a sidewall of the first trench. A thickness of the first part and a thickness of the second part are less than a thickness of the third part.

### BACKGROUND OF THE INVENTION

1. Field of the Invention

The present invention relates to a bidirectional semiconductor device and a method of fabricating the same, and more particularly, to a bidirectional semiconductor device having a gate insulating layer having a thickness at a bottom of a trench greater than a thickness at a sidewall of the trench and a method of fabricating the same.

2. Description of the Prior Art

A conventional bilateral conduction semiconductor device is disposed in a battery and is utilized to protect the battery from being damaged in a charging and discharging process. In order to have capability to protect the battery, the conventional bilateral conduction semiconductor device may be formed by two N-type power metal oxide semiconductor field effect transistors (MOSFETs), and drain electrodes of N-type power MOSFETs are electrically connected to each other. Each N-type power MOSFET includes a MOSFET and a PN diode, wherein a P-type region of the PN diode is electrically connected to a source electrode of the MOSFET, and an N-type region of the PN diode is electrically connected to a drain electrode of the MOSFET.

Please refer to FIG. 1. FIG. 1 is a schematic diagram illustrating a cross-sectional view of a conventional bidirectional semiconductor device according to the prior art. As shown in FIG. 1, the conventional bidirectional semiconductor device 10 includes a p-type substrate 12, and an n-type epitaxial layer 14 disposed on the p-type substrate 12, and the n-type epitaxial layer 14 has two trenches 16. Two p-type doped base regions 18 are disposed in the n-type epitaxial layer 14 respectively at two side of each trench 16, and two n-type doped source regions 20 are respectively disposed in two p-type doped base regions 18. Each n-type doped source region 20 respectively serves as a source of a power metal-oxide-semiconductor field-effect transistor (MOSFET). Two gate conductive layers 22 are disposed in two trenches 16 respectively, and each gate conductive layer 22 serves as a gate of an n-type MOSFET. An insulating layer 24 is disposed in each trench 16, and electrically insulates two gate conductive layers 22 from each other and electrically insulates the gate conductive layers 22 from the p-type doped base regions 18 and the n-type epitaxial layer 14. Thus, two source metal layers are disposed on the n-type doped source region 20.

As we could see from the above mentioned, in the conventional bidirectional semiconductor device 10, the n-type epitaxial layer 14 is formed on the p-type substrate 12 so as to form a depletion region between the p-type substrate and the n-type epitaxial layer 14. Thus, an ability of the n-type epitaxial layer 14 to tolerate voltage could be raised. However, the p-type substrate 12 and the n-type epitaxial layer 14 have different conductive types, so that an additional epitaxial process is required to form the n-type epitaxial layer 14 on the p-type substrate 12. Accordingly, the manufacturing cost is increased. Although another bidirectional semiconductor device manufactured on the n-type substrate is developed, the ability of the bidirectional semiconductor device to tolerate voltage is worse.

Therefore, to raise the ability of the bidirectional semiconductor device to tolerate voltage and reduce the manufacturing cost are objectives in this field.

### SUMMARY OF THE INVENTION

It is one of the objectives of the claimed invention to provide a bidirectional semiconductor device and a method of fabricating the same to raise the ability of the bidirectional semiconductor device to tolerate voltage and reduce the manufacturing cost.

According to one embodiment, a bidirectional semiconductor device is provided. The bidirectional semiconductor device includes a semiconductor substrate, a first doped base region, a second doped base region, a gate insulating layer, a first gate conductive layer, a second gate conductive layer, a first doped source region, and a second doped source region. The semiconductor substrate has a first conductive type, and the semiconductor substrate has a first trench. The first doped base region has a second conductive type, and the first doped base region is disposed in the semiconductor substrate at one side of the first trench. The second doped base region has the second conductive type, and the second doped base region is disposed in the semiconductor substrate at another side of the first trench. The gate insulating layer covers a surface of the first trench, and the gate insulating layer has a first part, a second part, and a third part. The first part is disposed adjacent to the first doped base region. The second is disposed adjacent to the second doped base region. The third part is disposed at a corner between a bottom and a sidewall of the first trench, and a thickness of the first part and a thickness of the second part are less than a thickness of the third part. The first gate conductive layer is disposed on the gate insulating layer adjacent to the first doped base region. The first part is disposed between the first gate conductive layer and the first doped base region. The second gate conductive layer is disposed on the gate insulating layer adjacent to the second doped base region, and the second gate conductive layer is insulated from the first gate conductive layer. The second part is disposed between the second gate conductive layer and the second doped base region. The first doped source region has the first conductive type, and the first doped source region is disposed in the first doped base region. The second doped source region has the second conductive type, and the second doped source region is disposed in the second doped base region.

According to another embodiment, a bidirectional semiconductor device is provided. The bidirectional semiconductor device includes a semiconductor substrate, a first doped base region, a second doped base region, a gate insulating layer, a first gate conductive layer, a second gate conductive layer, a first doped source region, a second doped source region, and a first contact plug and a second contact plug. The semiconductor substrate has a first conductive type, and the semiconductor substrate has a first trench. The first doped base region has a second conductive type, and the first doped base region is disposed in the semiconductor substrate at one side of the first trench. The second doped base region has the second conductive type, and the second doped base region is disposed in the semiconductor substrate at another side of the first trench. The gate insulating layer covers a surface of the first trench. The first gate conductive layer is disposed on the gate insulating layer adjacent to the first doped base region, and the second gate conductive layer is disposed on the gate insulating layer adjacent to the second doped base region. The second gate conductive layer is insulated from the first gate conductive layer. The first doped source region has the first conductive type, and the first doped source region is disposed in the first doped base region. The second doped source region has the second conductive type, and the second doped source region is disposed in the second doped base region. The first contact plug and the second contact plug are disposed on the first doped base region and the second doped base region respectively. The first contact plug is electrically connected to the first doped source region, and the second contact plug is electrically connected to the second doped source region. The first contact plug and the second contact plug partially overlap the first trench, and are electrically insulated from the first gate conductive layer and the second gate conductive layer.

According to another embodiment, a method of fabricating a bidirectional semiconductor device is provided. First, a semiconductor substrate is provided, and the semiconductor substrate has a first trench. The semiconductor substrate has a first conductive type. Next, a first insulating material layer and a filling material layer are formed in the first trench. Thereafter, a part of the first insulating material layer and a part of the filling material layer disposed in the first trench are removed to expose two sidewalls of the first trench. Then, the filling material layer remaining in the first trench is removed. Subsequently, a second insulating material layer is formed on the two sidewalls of the first trench and the first insulating material layer to form a gate insulating layer, and the gate insulating layer has a first part, a second part, and a third part. The first part and the second part are respectively disposed on the two sidewalls of the first trench, the third part is disposed at a corner between a bottom and a sidewall of the first trench, and a thickness of the first part and a thickness of the second part are less than a thickness of the third part. Next, a first ion implantation process and a first thermal drive-in process are performed to form a first doped base region and a second doped base region in the semiconductor substrate at two side of the first trench respectively. The first doped base region and the second doped base region have a second conductive type. After that, a second ion implantation process and a second thermal drive-in process are performed to form a first doped source region and a second doped source region in the first doped base region and the second doped base region respectively, and the first doped source region and the second doped source region have the first conductive type. Then, a first gate conductive layer and a second gate conductive layer are formed. The first gate conductive layer is disposed adjacent to the first doped base region, and the second gate conductive layer is disposed adjacent to the second doped base region.

The present invention increases the thickness of the gate insulating layer at the corners between the bottom and the sidewalls of each strip potion of the first trench by performing the step of forming the insulating material layer two times, and removes a part of the insulating material on a part of the sidewall of each strip portion between the steps of forming the insulating material layers, so that the thickness of the gate insulating layer on the sidewall of each strip potion of the first trench is less than the thickness of the gate insulating layer at the corners between the bottom and the sidewalls of each strip portion of the first trench. Thus, the ability of the bidirectional semiconductor device to tolerate voltage could be raised. Furthermore, the heights of each first gate conductive layer and each second gate conductive layer in each strip portion of the first trench in the present invention are etched to be less than the depth of the first trench, so that the insulating layer could be disposed between each first contact plug and each first gate conductive layer and between each second contact plug and each second gate conductive layer. Accordingly, each first contact plug could partially overlap the strip portions of the first trench disposed at two sides of the p-type first doped base region, and each second contact plug could partially overlap the strip portions of the first trench disposed at two sides of the p-type second doped base region. Thus, the size of the bidirectional semiconductor device could be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a conventional bidirectional semiconductor device according to the prior art.

FIG. 2 is a schematic diagram illustrating a top view of a bidirectional semiconductor device according to a preferred embodiment of the present invention.

FIG. 3 is a schematic diagram illustrating an enlarged view of a region A shown in FIG. 2.

FIG. 4 is a schematic diagram illustrating a cross-sectional view taken along a cross-sectional line A-A′ of FIG. 3.

FIG. 5 is a schematic diagram illustrating a cross-sectional view taken along a cross-sectional line B-B′ of FIG. 3.

FIG. 6 through FIG. 13 are schematic diagrams illustrating a method of fabricating a bidirectional semiconductor device according to a preferred embodiment of the present invention.

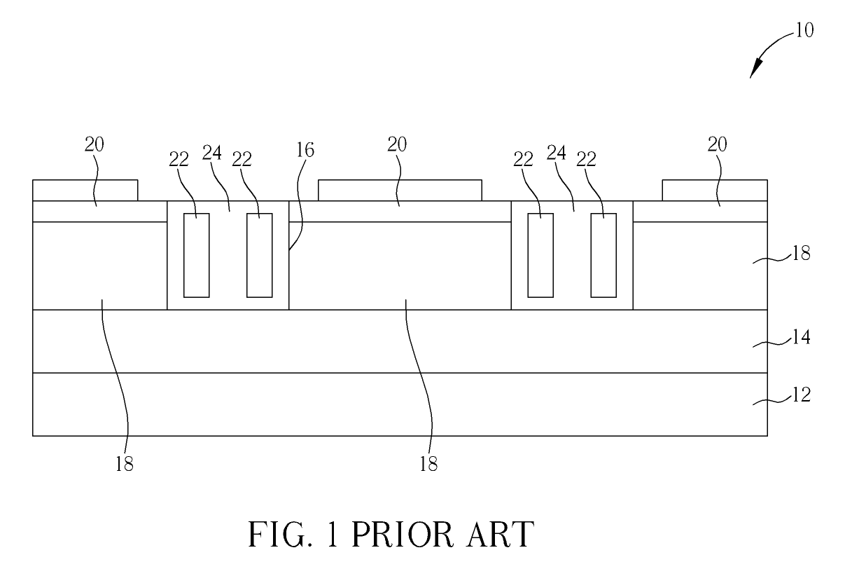

### DETAILED DESCRIPTION

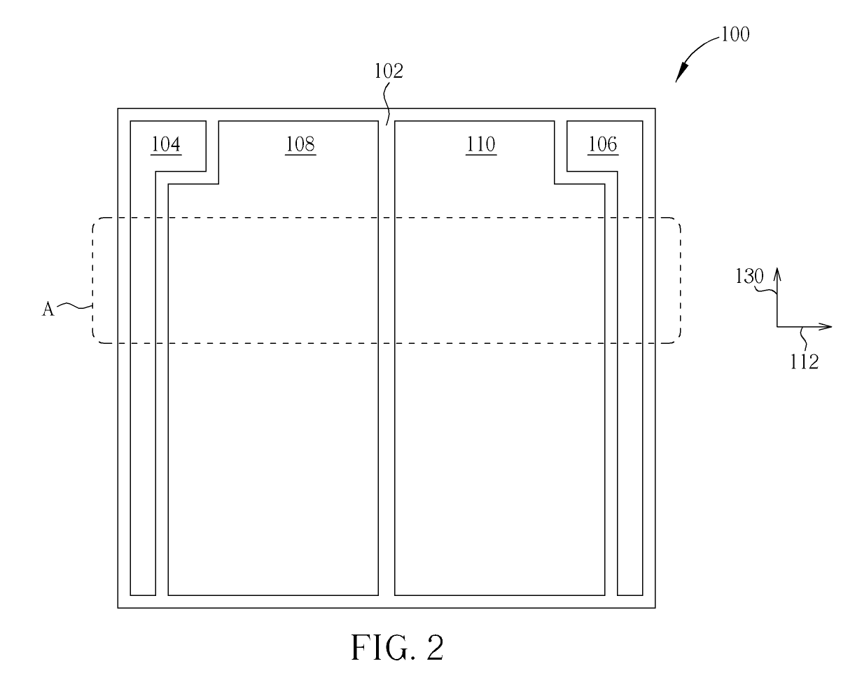

Please refer to FIG. 2, which is a schematic diagram illustrating a top view of a bidirectional semiconductor device according to a preferred embodiment of the present invention. As shown in FIG. 2, the bidirectional semiconductor device 100 includes a semiconductor substrate 102, a first gate metal layer 104, a second gate metal layer 106, a first source metal layer 108, and a second source metal layer 110. The first gate metal layer 104, the first source metal layer 108, the second source metal layer 110 and the second gate metal layer 106 are disposed on the semiconductor substrate 102, and are arranged in sequence along a first direction 112. The first gate metal layer 104 and the first source metal layer 108 are utilized to electrically connect a gate and a source of a first metal-oxide-semiconductor field-effect transistor (MOSFET) of the bidirectional semiconductor device 100 to the outside, and the second gate metal layer 106 and the second source metal layer 110 are utilized to electrically connect a gate and a source of a second metal-oxide-semiconductor field-effect transistor (MOSFET) of the bidirectional semiconductor device 100 to the outside.

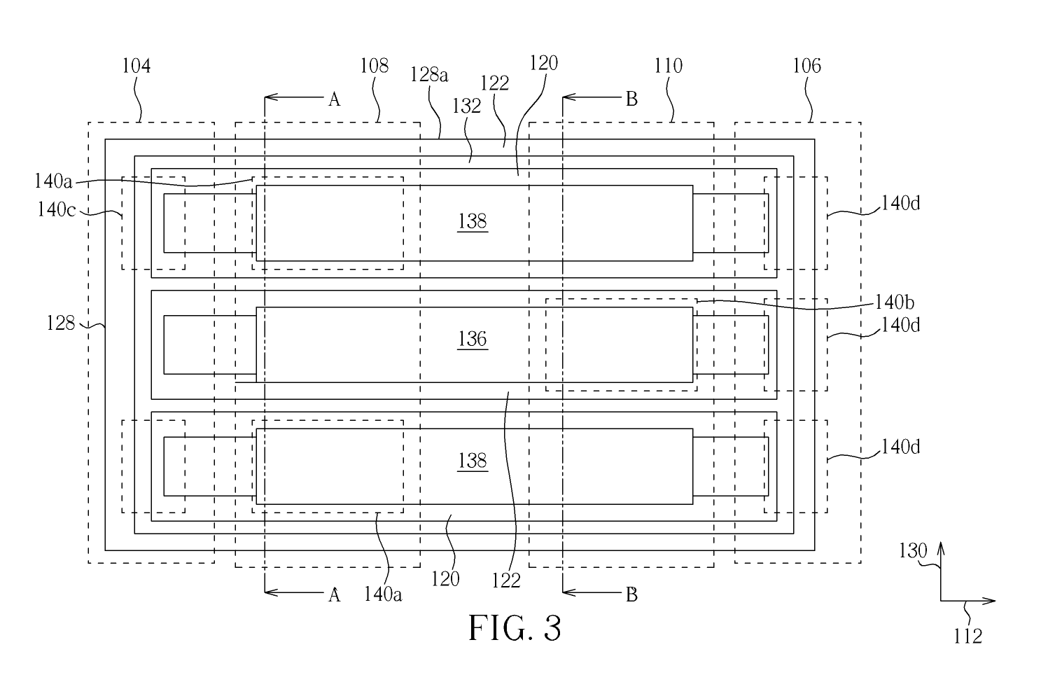

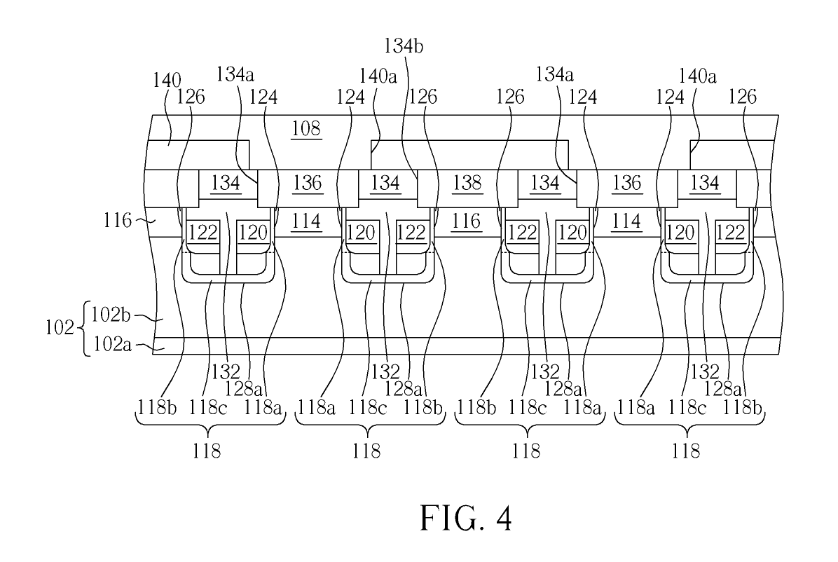

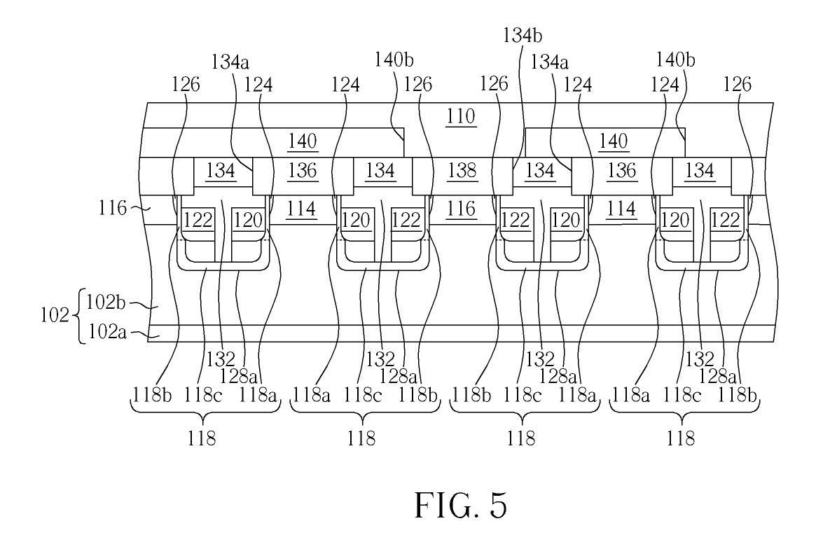

The structure of the bidirectional semiconductor device 100 is further detailed in the following description. Please refer to FIG. 3 through FIG. 5. FIG. 3 is a schematic diagram illustrating an enlarged view of a region A shown in FIG. 2, FIG. 4 is a schematic diagram illustrating a cross-sectional view taken along a cross-sectional line A-A′ of FIG. 3, and FIG. 5 is a schematic diagram illustrating a cross-sectional view taken along a cross-sectional line B-B′ of FIG. 3. As shown in FIG. 3 through FIG. 5, the bidirectional semiconductor device 100 in this embodiment includes a plurality of first doped base regions 114, a plurality of second doped base regions 116, agate insulating layer 118, a plurality of first gate conductive layers 120, a plurality of gate conductive layers 122, a plurality of first doped source regions 124, and a plurality of second doped source regions 126. The semiconductor substrate 102, the first doped source regions 124, and the second doped source regions 126 have a first conductive type, and the first doped base regions 114 and the second doped base regions 116 have a second conductive type different from the first conductive type. In this embodiment, the first conductive type is n type, and the second conductive type is p type. The first conductive type and the second conductive type of the present invention are not limited herein and could also be exchanged. The n-type semiconductor substrate 102 serves as a drain of the first MOSFET, and also serves as a drain of the second MOSFET, so that the drain of the first MOSFET and the drain of the second MOSFET are electrically connected to each other. In addition, the n-type semiconductor substrate 102 in this embodiment is composed of an n-type substrate 102a and an n-type epitaxial layer 102b disposed on the n-type substrate 102a, but is not limited thereto. The n-type semiconductor substrate 102 has a first trench 128. In this embodiment, the first trench 128 is comb-shaped, and has a plurality of strip portions 128a arranged in sequence along a second direction 130. Each p-type doped base region 114 and each p-type second doped base region 116 are respectively disposed in the n-type semiconductor substrate 102 between any two of the strip portions 128a adjacent to each other, and are arranged alternatively and sequentially along the second direction 130. Each p-type first doped base region 114 serves as a base of the first MOSFET, and each p-type second doped base region 116 serves as a base of the second MOSFET. The gate insulating layer 118 covers a surface of the first trench 128. Each first gate conductive layer 120 is disposed on the gate insulating layer 118 in each strip portion 128a of the first trench 128 respectively, and located on a sidewall of each strip portion 128a adjacent to the p-type first doped base region 114 to serve as the gate of the first MOSFET. Each second gate conductive layer 122 is disposed on the gate insulating layer 118 in each strip portion 128a of the first trench 128 respectively, and located on a sidewall of each strip portion 128a adjacent to the p-type second doped base region 116 to serve as the gate of the second MOSFET. In other words, each p-type first doped base region 114 and each p-type second doped base region 116 adjacent to each other are disposed on two sidewalls of each strip portion 128a respectively. In each strip portion 128a, the first gate conductive layer 120 is disposed adjacent to the p-type first doped base region 114, and the second gate conductive layer 122 is disposed adjacent to the p-type second doped base region 116. Furthermore, the gate insulating layer 118 electrically insulates the first gate conductive layers 120 from the n-type semiconductor substrate 102. The gate insulating layer 118 electrically insulates the second gate conductive layers 122 from the n-type semiconductor substrate 102. The gate insulating layer 118 electrically insulates the first gate conductive layers 120 from the second gate conducive layers 122. Moreover, any two of the n-type first doped source regions 124 adjacent to each other are respectively disposed in each p-type first doped base region 114, and are in contact with two strip portions 128a adjacent to the p-type first doped base region 114 respectively, so that the two n-type first doped source regions 124 serve as the source of the first MOSFET. Any two of the n-type second doped source regions 124 adjacent to each other are respectively disposed in each p-type second doped base region 116, and are in contact with two strip portions 128a adjacent to the p-type second doped base region 116 respectively, so that the two n-type second doped source regions 126 serve as the source of the second MOSFET.

In this embodiment, the gate insulating layer 118 in each strip portion 128a has a first part 118a, a second part 118b, and a third part 118c. Each first part 118a is disposed adjacent to each p-type first doped base region 114 respectively, and is located between each first gate conductive layer 120 and each p-type first doped baser region 114, so that each first part 118a serves as the gate insulating layer of the first MOSFET. Each second part 118b is disposed adjacent to each p-type second doped base region 116, and is located between each second gate conductive layer 122 and each p-type second doped base region 116, so that each second part 118b serve as the gate insulating layer of the second MOSFET. Each third part 118c is disposed at the bottom of the first trench 128; that is, each third part 118c is disposed between first conductive layer 120 and the n-type semiconductor substrate 102 and between the second gate conductive layer 122 and the n-type semiconductor substrate 102. In addition, a thickness of each first part 118a and a thickness of each second part 118b, such as substantially between 200 angstroms and 300 angstroms, are less than a thickness of each third part 118c, such as substantially between 500 angstroms and 800 angstroms. Thus, the electric field that each third part 118c could tolerate is higher than that each first part 118a and each second part 118b could tolerate. It should be noted that when a high voltage is applied to the source of the first MOSFET of the bidirectional semiconductor device 100, a high electric field extends from the n-type semiconductor substrate 102 between first gate conductive layers 120 to the n-type semiconductor substrate 102 at the bottom of the first trench 128, and a density of the electric field applied to a corner between the bottom and the sidewalls of the first trench 128 would be higher than a density of the electric field applied to the bottom and the sidewalls of the first trench 128 due to an effect of concentrated electric field. In this embodiment, the thickness of the gate insulating layer 118 at the corner between the bottom and the sidewalls of the first trench 128 is increased to reduce the density of the electric field at the corner between the bottom and the sidewalls of the first trench 128, so that the ability to tolerate voltage of the bidirectional semiconductor device 100 could be raised, and the breakdown voltage of the bidirectional semiconductor device 100 could be increased. Furthermore, in this embodiment, each third part 118c could also extend onto a part of each sidewall of the first trench 128, but the present invention is not limited thereto. Each third part 118c could be only disposed at the corner between the bottom and the sidewalls of the first trench to reduce the density of the electric field at the corner between the bottom and the sidewalls of the first trench.

In addition, the bidirectional semiconductor device 100 of this embodiment further includes an insulating layer 132, a first dielectric layer 134, a plurality of first contact plugs 136, a plurality of second contact plugs 138, and a second dielectric layer 140. The insulating layer 132 is disposed between each first gate conductive layer 120 and each second gate conductive layer 122 in the first trench 128 so as to electrically insulate the first gate conductive layers 120 from the second gate conductive layers 122. Furthermore, a height of each first gate conductive layer 120 and a height of each second gate conductive layer 122 in the first trench 128 is less than a height of the first trench 128, and the insulating layer 132 extends onto each first gate conductive layer 120 and each second gate conductive layer 122 in each strip portion 128a so as to fill up the first trench 128. The first dielectric layer 134 is disposed on the n-type semiconductor substrate 102 and the insulating layer 132, and has a plurality of first through holes 134a and a plurality of second through holes 134b. Each first through hole 134a and each second through hole 134b are arranged alternatively and sequentially along the second direction 130. Each first through hole 134a exposes each p-type first doped base region 114, two adjacent n-type first doped source regions 124, and the insulating layer 132, and each second through hole 134b exposes each p-type second doped base region 116, two adjacent n-type second doped source regions 126, and the insulating layer 132. Each first contact plug 136 fills up each first through hole 134a, and is disposed on and in contact with each p-type first doped base region 114. Each second contact plug 138 fills up each second through hole 134b, and is disposed on and in contact with each p-type second doped base region 116. Accordingly, each first contact plug 136 and each second contact plug 138 are also arranged alternatively and sequentially along the second direction 130.

It should be noted that since the heights of each first gate conductive layer 120 and each second gate conductive layer 122 are less than a height of the first trench 128, the insulating layer 132 is disposed between each first contact plug 136 and the first gate conductive layer 120, and electrically insulates each contact plug 136 from each first gate conductive layer 120. The insulating layer 132 is also disposed between each second contact plug 138 and each second gate conductive layer 122, and electrically insulates each second contact plug 138 from each second gate conductive layer 122. Furthermore, each first contact plug 136 could partially overlap two adjacent strip portions of the first trench 128 respectively disposed at two sides of each p-type first doped base region 114, and each second contact plug 138 could partially overlap two adjacent strip portions of the first trench 128 disposed at two sides of each p-type second doped base region 116. Thus, in this embodiment, a distance between any two of the strip portions 128a of the first trench 128 adjacent to each other is not limited to a width of each first contact plug 136 and a width of each second contact plug in the second direction 130, and each first contact plug 136 partially overlapping each first gate conductive layer 120 and each second contact plug 138 partially overlapping each second conductive layer 122 in the bidirectional semiconductor device 100 could reduce the distance between any two of the strip portions 128a adjacent to each other, and further decrease the size of the bidirectional semiconductor device 100.

Moreover, the second dielectric layer 140 is disposed on the first contact plugs 136, the second contact plugs 138 and the first dielectric layer 134, and has a plurality of third through holes 140a and a plurality of fourth through holes 140b. Each third through hole 140a exposes each first contact plug 136, and each fourth through hole 140b exposes each second contact plug 138. The first source metal layer 108 is disposed on the second dielectric layer 140, and fills into the third through holes 140a so as to be in contact with the first contact plugs 136. Accordingly, the first source metal layer 108 could be electrically connected to the n-type first doped source regions 124 through the first contact plugs 136. The second source metal layer 110 is disposed on the second dielectric layer 140, and fills into the fourth through holes 140b so as to be in contact with the second contact plugs 138. Accordingly, the second source metal layer 110 could be electrically connected to the n-type second doped source regions 126 through the second contact plugs 138. Furthermore, the second dielectric layer 140 further has a plurality of fifth through holes 140c and a plurality of sixth through holes 140d. The first gate metal layer 104 is disposed on the second dielectric layer 140, and is electrically connected to the first gate conductive layers 120 through the fifth through holes 140c. The second gate metal layer 106 is disposed on the second dielectric layer 140, and is electrically connected to the second gate conductive layers 122 through the sixth through holes 140d.

In the present invention, the first trench is not limited to have a plurality of strip portions, and could also have only one strip portion. The number of the strip portion is determined by the required turn-on current of the bidirectional semiconductor device. Accordingly, the bidirectional semiconductor device in the present invention is also not limited to have a plurality of p-type first doped base regions, a plurality of p-type second doped base regions, a plurality of first gate conductive layers, a plurality of n-type first doped source regions, and a plurality of n-type second doped source regions, and could also have only one p-type first doped base region, one p-type second doped base region, one first gate conductive layer, one n-type first doped source region, and one n-type second doped source region. The numbers of the p-type first doped base region, the p-type second doped base region, the first gate conductive layer, the n-type first doped source region, and the n-type second doped source region are determined by the number of the formed strip portion.

According to the above-mentioned description, the thickness of the gate insulating layer 118 at the corner between the bottom and the sidewalls of the first trench 128 is increased to reduce the density of the electric field at the corner between the bottom and the sidewalls of the first trench 128 in this embodiment, so that the ability to tolerate voltage of the bidirectional semiconductor device 100 could be raised, and the breakdown voltage of the bidirectional semiconductor device 100 could be increased. Furthermore, the heights of the first gate conductive layer 120 and the second gate conductive layer 122 are less than a height of the first trench 128, so that each first contact plug 136 could partially overlap the first trench 128 at two sides of each p-type first doped base region 120, and each second contact plug 138 could partially overlap the first trench 128 at two sides of each p-type second doped base region 122. The size of the bidirectional semiconductor device 100 could be accordingly decreased.

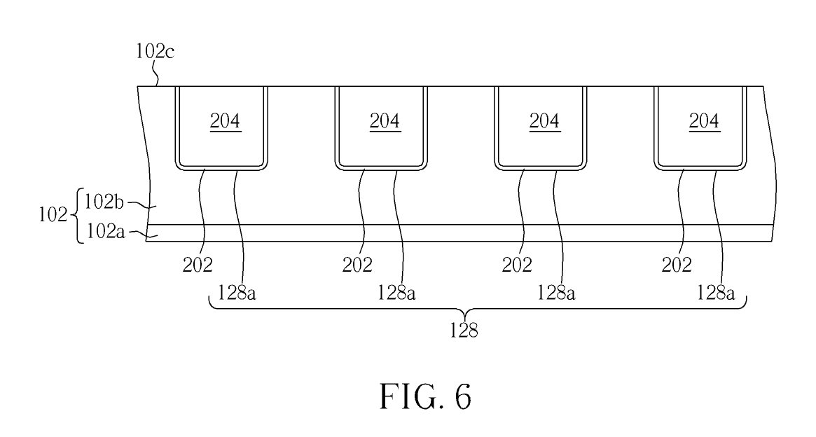

The method of fabricating the bidirectional semiconductor device 100 in this embodiment would be detailed in the following description. Please refer to FIG. 6 through FIG. 13 together with FIG. 3 through FIG. 5. FIG. 6 through FIG. 13 are schematic diagrams illustrating a method of fabricating a bidirectional semiconductor device according to a preferred embodiment of the present invention. As shown in FIG. 6, the n-type semiconductor substrate 102, such as silicon wafer composed of monocrystalline silicon, is first provided. Then, a mask is utilized to form the first trench 128 having the strip portions 128a on the top surface 102c of the n-type semiconductor substrate 102. Next, a first insulating material layer 202 and a filling material layer 204 are sequentially formed to cover the strip portions 128a and the n-type semiconductor substrate 102. Then, the first insulating material layer 202 and the filling material layer 204 outside the first trench 128 are removed. The filling material layer 204 is composed of a material, such as polysilicon, which has a high etching selectivity with respect to the n-type semiconductor substrate 102 and the first insulating material layer 202.

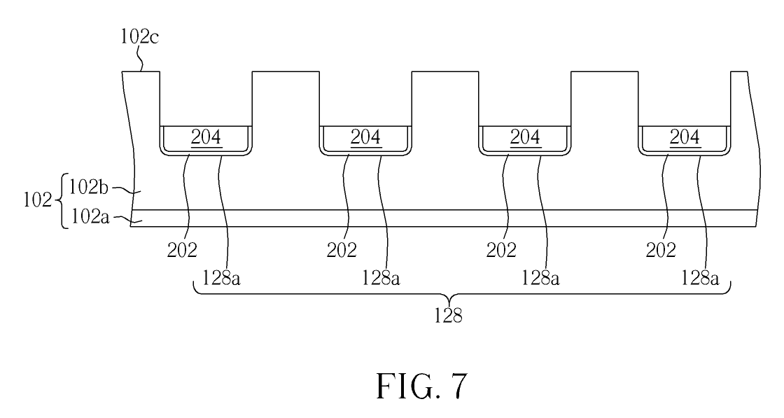

As shown in FIG. 7, next, an etching process is performed to remove a part of the first insulating material layer 202 and a part of filling material layer 204 in each strip portion 128a so as to expose two sidewalls of each strip portion 128a by utilizing the high etching selectivity of the filling material layer 204 with respect to the n-type semiconductor substrate 102 and the high etching selectivity of the first insulating material layer 202 with respect to the n-type semiconductor substrate 102. A distance between a exposed surface of the first insulating material layer 202 and the exposed filling material layer 204 and a top surface 102c of the n-type semiconductor substrate 102 is greater than a distance between bottoms of the p-type first doped base region 114 and the p-type second doped base region 116 formed in the following step and the top surface 102c of the n-type semiconductor substrate 102, but the present invention is not limited thereto. The remaining first insulating material layer 202 and the remaining filling material layer 204 at least cover the corners between the bottom and the sidewalls of each strip portion 128a in the present invention.

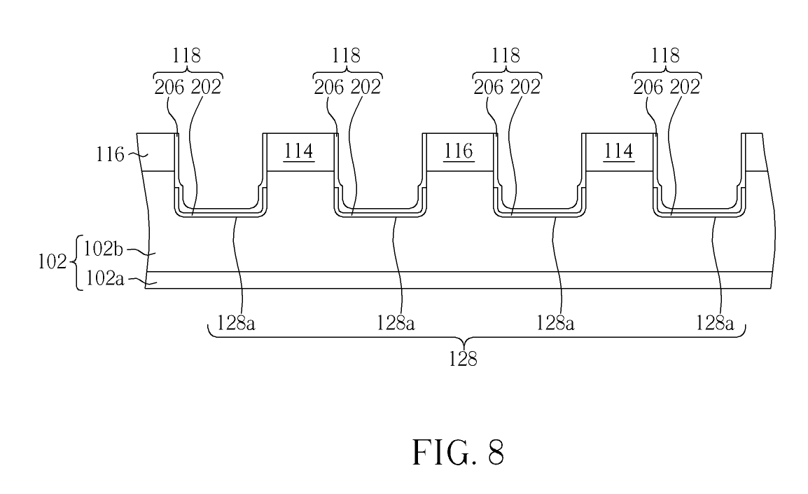

As shown in FIG. 8, another etching process is then performed to remove the remaining filling material layer 204 by utilizing the high etching selectivity of the filling material layer 204 with respect to the n-type semiconductor substrate 102 and the high etching selectivity of the filling material layer 204 with respect to the first insulating material layer 202. Next, a second insulating material layer 206 is formed on the two exposed sidewalls of each strip portion 128a and the first insulating material layer 202, so that a gate insulating layer 118 is formed. The first part 118a of the gate insulating layer 118 is formed by the second insulating material 206 formed on a sidewall of each strip portion 128a, and the second part 118b of the gate insulating layer 118 is formed by the second insulating material layer 206 formed on another sidewall of each strip portion 128a. Furthermore, the third part 118c of the gate insulating layer 118 is formed by the remaining first insulating material layer 202 and the second insulating material layer 206 on the first insulating material layer 202, and a thickness of the third part 118c is accordingly greater than a thickness of the first part 118a and a thickness of the second part 118b. In this embodiment, the steps of forming the first insulating material layer 202 and the second insulating material layer 206 can utilize thermal oxidation process, but the present invention is not limited thereto.

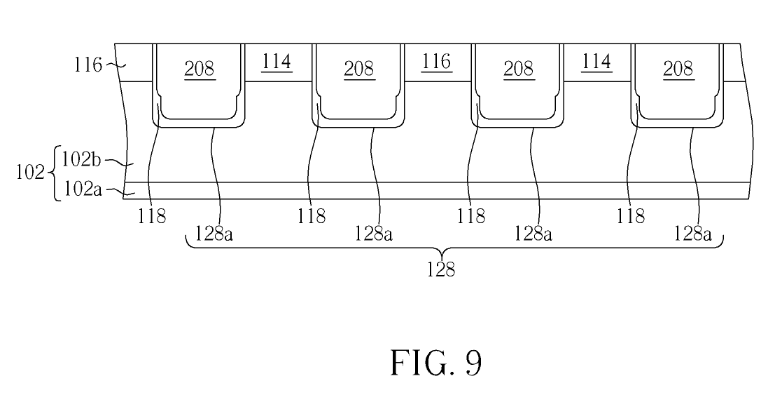

As shown in FIG. 9, a conductive layer 208, such as polysilicon, is subsequently formed in each strip portion 128a. Then, a first ion implantation process and a first thermal drive-in process are performed to form each p-type first doped base region 114 and each p-type second doped base region 116 respectively in the n-type semiconductor substrate 102 at two sides of each strip portion 128a. Each p-type first doped base region 114 and each p-type second doped base region 116 are arranged alternatively and sequentially along the second direction 130.

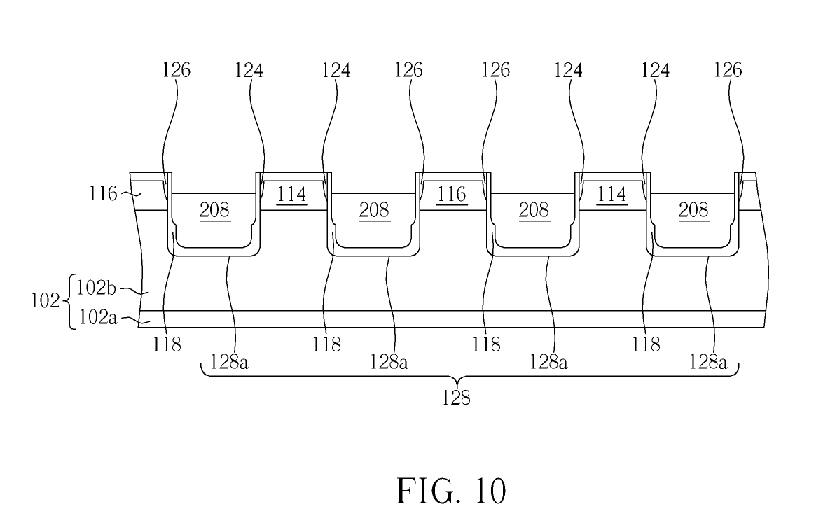

As shown in FIG. 10, a part of conductive layer 208 is removed thereafter. A distance between a surface of the remaining conductive layer 208 and the top surface 102c of the n-type semiconductor substrate 102 is less than a distance between bottoms of the formed p-type first doped base region 114 and the formed p-type second doped base region 116 and the top surface 102c of the n-type semiconductor substrate 102. Next, a second ion implantation process and a second thermal drive-in process are performed to form the n-type first doped source regions in each p-type first doped base region 114 and form the n-type second doped source regions in each p-type second doped base region 116. Since the distance between the surface of the remaining conductive layer 208 and the top surface 102c of the n-type semiconductor substrate 102 is less than the depths of the formed p-type first doped base region 114 and the formed p-type second doped base region 116, the formed n-type first doped source regions 124 and the n-type second doped source regions 126 would not be in contact with the n-type semiconductor substrate 102 under the p-type first doped base region 114 and the p-type second doped base region 116.

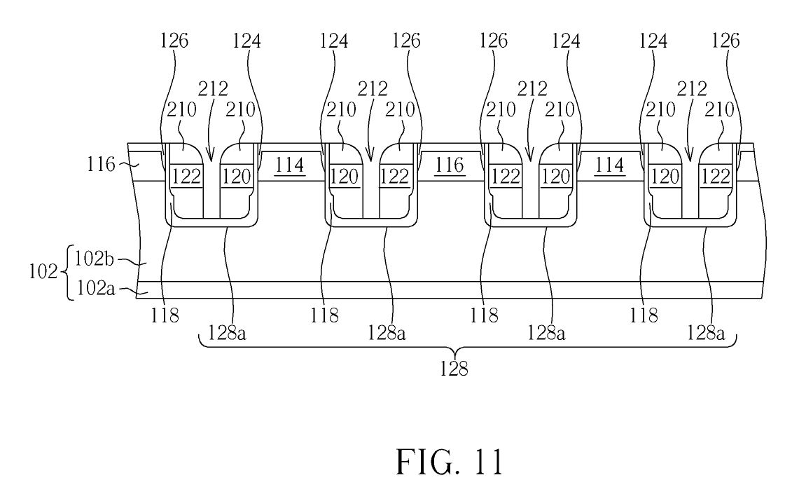

As shown in FIG. 11, subsequently, a third insulating material layer is formed on the conductive layer 208 and the n-type semiconductor substrate 102. Another blanket etching process is then performed to form two spacers 210 on the conductive layer 208 in each strip portion 128a. The two spacers 210 are respectively adjacent to the two sidewalls of each strip portion 128a, and expose the conductive layer 208 disposed between them. Next, the two spacers 210 is utilized to be a mask to forma second trench 212 in the remaining conductive layer 208, and the first gate conductive layer 120 and the second gate conductive layer 122 are formed on the gate insulating layer 118. The first gate conductive layer 120 is disposed adjacent to the p-type first doped base region 114, and the second gate conductive layer 122 is disposed adjacent to the p-type second doped base region 116.

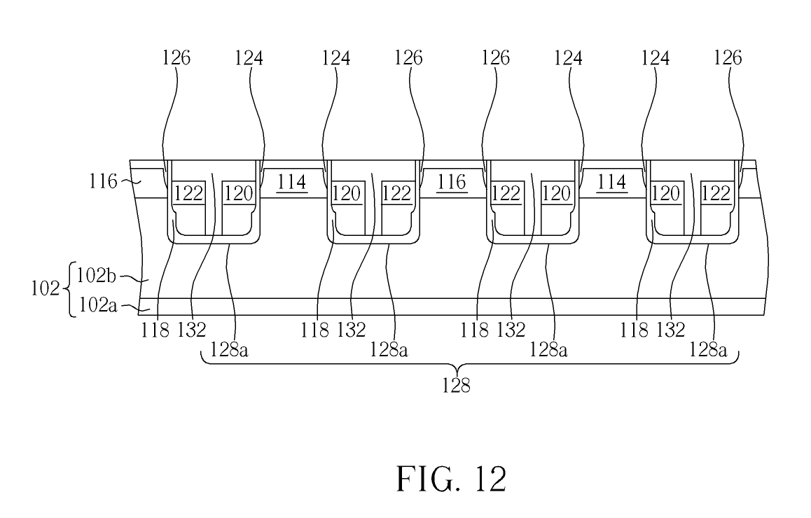

As shown in FIG. 12, next, a fourth insulating material layer is formed between the first gate conductive layer 120 and the second gate conductive layer 122 in each strip portion 128a to fill each strip portion 128a, and the insulating layer 132 is constituted by each fourth insulating material layer and the two spacers 210.

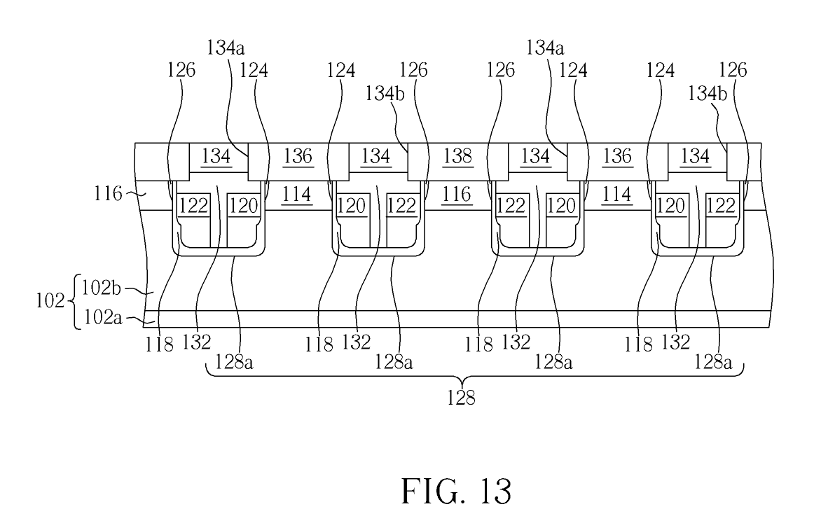

As shown in FIG. 13, the first dielectric layer 134 is then formed on the insulating layer 132 and the n-type semiconductor substrate 102. Thereafter, a photolithographic and etching process is performed to form the first through holes 134a and the second through hole 134b in the first dielectric layer 134 and remove a part of the insulating layer 132, a part of n-type first doped source regions 124, a part of n-type second doped source regions 126 and a part of gate insulating layer 118. Then, the first contact plugs 136 are formed in the first through holes 134a respectively, and the second contact plugs 138 are formed in the second through holes 134b respectively. Since the step of forming the first through holes 134a and the second through holes 134b would remove a part of n-type first doped source regions 124 disposed on each p-type first doped base region 114 and a part of n-type second doped source regions 126 disposed on each p-type second doped base region 116, the first contact plugs 136 could electrically connect the n-type first doped source regions 124 and the p-type first doped base regions 114, and the second contact plugs 138 could electrically connect the n-type second doped source regions 126 and the p-type second doped base regions 116. In other embodiments of the present invention, p-type doped contact regions could be further formed in each p-type first doped base region 114 and each p-type second doped base region 116 respectively between the step of forming the first through holes 134a and the second through hole 134b and the step of forming the first contact plugs 136 and the second contact plugs 138.

As shown in FIG. 3 through FIG. 5, the second dielectric layer 140 is thereafter formed on the first dielectric layer 134, the first contact plugs 136 and the second contact plugs 138. Then, another photolithographic and etching process is performed to the third through holes 140a, the fourth through holes 140b, the fifth through hole 140c and the sixth through hole 140d in the second dielectric layer 140. Finally, the first source metal layer 108, the second source metal layer 110, the first gate metal layer 104 and the second gate metal layer 106 are formed on the second dielectric layer 140, and the bidirectional semiconductor device 100 of this embodiment is completed.

In summary, the present invention increases the thickness of the gate insulating layer at the corners between the bottom and the sidewalls of each strip potion of the first trench by performing the step of forming the insulating material layer two times, and removes a part of the insulating material on a part of the sidewall of each strip portion of the first trench between the steps of forming the insulating material layers, so that the thickness of the gate insulating layer on the sidewall of each strip portion is less than the thickness of the gate insulating layer at the corners between the bottom and the sidewalls of each strip portion. Thus, the ability of the bidirectional semiconductor device to tolerate voltage could be raised. Furthermore, the heights of each first gate conductive layer and each second gate conductive layer in each strip portion in the present invention are etched to be less than the depth of the first trench, so that the insulating layer could be disposed between each first contact plug and each first gate conductive layer and between each second contact plug and each second gate conductive layer. Accordingly, each first contact plug could partially overlap the strip portions of the first trench disposed at two sides of the p-type first doped base region, and each second contact plug could partially overlap the strip portions of the first trench disposed at two sides of the p-type second doped base region. Thus, the size of the bidirectional semiconductor device could be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bidirectional semiconductor device, comprising:
a semiconductor substrate, having a first conductive type, and the semiconductor substrate having a first trench;
a first doped base region, having a second conductive type, the first doped base region being disposed in the semiconductor substrate at one side of the first trench;
a second doped base region, having the second conductive type, the second doped base region being disposed in the semiconductor substrate at another side of the first trench;
a gate insulating layer, covering a surface of the first trench, and the gate insulating layer having a first part, a second part, and a third part, wherein the first part is disposed adjacent to the first doped base region, the second is disposed adjacent to the second doped base region, the third part is disposed at a corner between a bottom and a sidewall of the first trench, and a thickness of the first part and a thickness of the second part are less than a thickness of the third part;
a first gate conductive layer, disposed on the gate insulating layer adjacent to the first doped base region, wherein the first part is disposed between the first gate conductive layer and the first doped base region;
a second gate conductive layer, disposed on the gate insulating layer adjacent to the second doped base region, and the second gate conductive layer being insulated from the first gate conductive layer, wherein the second part is disposed between the second gate conductive layer and the second doped base region;
a first doped source region, having the first conductive type, and the first doped source region being disposed in the first doped base region; and
a second doped source region, having the second conductive type, and the second doped source region being disposed in the second doped base region.

2. The bidirectional semiconductor device according to claim 1, further comprising a first contact plug and a second contact plug, disposed on the first doped base region and the second doped base region respectively, and the first contact plug and the second contact plug partially overlapping the first trench.

3. The bidirectional semiconductor device according to claim 2, further comprising an insulating layer, disposed between the first contact plug and the first gate conductive layer and between the second contact plug and the second gate conductive layer.

4. The bidirectional semiconductor device according to claim 3, wherein the insulating layer extends to be between the first gate conductive layer and the second gate conductive layer to electrically insulate the first gate conductive layer from the second gate conductive layer.

5. The bidirectional semiconductor device according to claim 2, further comprising a first dielectric layer, disposed between the first contact plug and the second contact plug.

6. The bidirectional semiconductor device according to claim 2, further comprising a first source metal layer and a second source metal layer, disposed on the first contact plug and the second contact plug, wherein the first source metal layer is electrically connected to the first doped source region through the first contact plug, and the second source metal layer is electrically connected to the second doped source region through the second contact plug.

7. The bidirectional semiconductor device according to claim 6, further comprising a second dielectric layer, disposed between the first contact plug and the second source metal layer and between the second contact plug and the first source metal layer.

8. A bidirectional semiconductor device, comprising:
a semiconductor substrate, having a first conductive type, and the semiconductor substrate having a first trench;
a first doped base region, having a second conductive type, the first doped base region being disposed in the semiconductor substrate at one side of the first trench;
a second doped base region, having the second conductive type, the second doped base region being disposed in the semiconductor substrate at another side of the first trench;
a gate insulating layer, covering a surface of the first trench;
a first gate conductive layer, disposed on the gate insulating layer adjacent to the first doped base region;
a second gate conductive layer, disposed on the gate insulating layer adjacent to the second doped base region, and the second gate conductive layer being insulated from the first gate conductive layer;
a first doped source region, having the first conductive type, and the first doped source region being disposed in the first doped base region;
a second doped source region, having the second conductive type, and the second doped source region being disposed in the second doped base region; and
a first contact plug and a second contact plug, disposed on the first doped base region and the second doped base region respectively, the first contact plug being electrically connected to the first doped source region, and the second contact plug being electrically connected to the second doped source region, wherein the first contact plug and the second contact plug partially overlap the first trench, and are electrically insulated from the first gate conductive layer and the second gate conductive layer.

9. The bidirectional semiconductor device according to claim 8, wherein the gate insulating layer has a first part, a second part, and a third part, wherein the first part is disposed between first gate conductive layer and the first doped base region, the second is disposed between the second gate conductive layer and the second doped base region, the third part is disposed at a corner between a bottom and a sidewall of the first trench, and a thickness of the first part and a thickness of the second part are less than a thickness of the third part.

10. The bidirectional semiconductor device according to claim 8, further comprising an insulating layer, disposed between the first contact plug and the first gate conductive layer and between the second contact plug and the second gate conductive layer.

11. The bidirectional semiconductor device according to claim 10, wherein the insulating layer extends to be between the first gate conductive layer and the second gate conductive layer to electrically insulate the first gate conductive layer from the second gate conductive layer.

12. The bidirectional semiconductor device according to claim 8, further comprising a first dielectric layer, disposed between the first contact plug and the second contact plug.

13. The bidirectional semiconductor device according to claim 8, further comprising a first source metal layer and a second source metal layer, disposed on the first contact plug and the second contact plug, wherein the first source metal layer is electrically connected to the first doped source region through the first contact plug, and the second source metal layer is electrically connected to the second doped source region through the second contact plug.

14. The bidirectional semiconductor device according to claim 13, further comprising a second dielectric layer, disposed between the first contact plug and the second source metal layer and between the second contact plug and the first source metal layer.

15. A method of fabricating a bidirectional semiconductor device, comprising:
providing a semiconductor substrate, the semiconductor substrate having a first trench, wherein the semiconductor substrate has a first conductive type;
forming a first insulating material layer and a filling material layer in the first trench;
removing a part of the first insulating material layer and a part of the filling material layer disposed in the first trench to expose two sidewalls of the first trench;
removing the filling material layer remaining in the first trench;
forming a second insulating material layer on the two sidewalls of the first trench and the first insulating material layer to form a gate insulating layer, and the gate insulating layer having a first part, a second part, and a third part, wherein the first part and the second part are respectively disposed on the two sidewalls of the first trench, the third part is disposed at a corner between a bottom and a sidewall of the first trench, and a thickness of the first part and a thickness of the second part are less than a thickness of the third part;
performing a first ion implantation process and a first thermal drive-in process to form a first doped base region and a second doped base region in the semiconductor substrate at two side of the first trench respectively, wherein the first doped base region and the second doped base region have a second conductive type;
performing a second ion implantation process and a second thermal drive-in process to form a first doped source region and a second doped source region in the first doped base region and the second doped base region respectively, wherein the first doped source region and the second doped source region have the first conductive type; and
forming a first gate conductive layer and a second gate conductive layer, wherein the first gate conductive layer is disposed adjacent to the first doped base region, and the second gate conductive layer is disposed adjacent to the second doped base region.

16. The method of fabricating a bidirectional semiconductor device according to claim 15, wherein the step of forming the first gate conductive layer and the second gate conductive layer comprises:
forming a conductive layer in the first trench before performing the first ion implantation process and the first thermal drive-in process;
removing a part of the conductive layer between the step of performing the first ion implantation process and the first drive-in process and the step of performing the second ion implantation process and the second drive-in process; and
forming a second trench in the conductive layer to form the first gate conductive layer and the second gate conductive layer.

17. The method of fabricating a bidirectional semiconductor device according to claim 16, wherein the step of forming the second trench comprises:
forming two spacers on the conductive layer, the two spacers being disposed adjacent to the two sidewalls respectively and exposing the conductive layer between the two spacers; and
removing the conductive layer between the two spacers to form the second trench.

18. The method of fabricating a bidirectional semiconductor device according to claim 17, wherein the second ion implantation process and the second drive-in process are performed between the step of removing a part of the conductive layer and the step of forming the two spacers.

19. The method of fabricating a bidirectional semiconductor device according to claim 17, wherein after the step of forming the first gate conductive layer and the second gate conductive layer, the method further comprises forming an insulating layer between the first gate conductive layer and the second gate conductive layer.

20. The method of fabricating a bidirectional semiconductor device according to claim 19, further comprising forming a first dielectric layer on the insulating layer and the semiconductor substrate.

21. The method of fabricating a bidirectional semiconductor device according to claim 20, further comprising forming a first contact plug and a second contact plug in the first dielectric layer, the first contact plug being electrically connected to the first doped source region, and the second contact plug being electrically connected to the second doped source region, wherein the first contact plug and the second contact plug partially overlap the first trench, and are electrically insulated from the first gate conductive layer and the second gate conductive layer.

22. The method of fabricating a bidirectional semiconductor device according to claim 21, further comprising:
forming a second dielectric layer on the first dielectric layer, the first contact plug and the second contact plug; and
forming a first source metal layer and a second source metal layer, wherein the first source metal layer is electrically connected to the first contact plug, and the second source metal layer is electrically connected to the second contact plug.
